(19) United States
(12) Patent Application Publication
(10) Pub. No.: US 2026/0032802 A1
(43) Pub. Date: Jan. 29, 2026

(54) ELECTRONIC DEVICE COMPRISING HEAT TRANSFER PORTION

(71) Applicant: Samsung Electronics Co., Ltd., Suwon-si (KR)

(72) Inventors: Min PARK, Suwon-si (KR); Yoonhee CHANG, Suwon-si (KR); Jieun HWANG, Suwon-si (KR); Jinhwan JUNG, Suwon-si (KR); Jihyeon SON, Suwon-si (KR); Jeonggen YOON, Suwon-si (KR)

(21) Appl. No.: 19/281,194

(22) Filed: Jul. 25, 2025

Related U.S. Application Data
(63) Continuation of application No. PCT/KR2025/010297, filed on Jul. 14, 2025.

(30) Foreign Application Priority Data
Jul. 26, 2024 (KR) 10-2024-0099262
Sep. 9, 2024 (KR) 10-2024-0122638

(51) Int. Cl. H05K 1/02

(52) U.S. Cl. CPC H05K 1/0203; H05K 2201/06; H05K 2201/0715; H05K 2201/10371

(57) ABSTRACT

An electronic device may include: a housing and a board assembly disposed inside the housing. The board assembly may include a printed circuit board having a first surface and a second surface, an electronic component disposed on the first surface of the board assembly, a shielding portion disposed on the first surface and surrounding the electronic component, the shielding portion including a first support portion forming a receiving space and a shielding sheet covering the receiving space, and a heat transfer portion disposed between the electronic component and the shielding sheet and configured to exchange heat with the electronic component, wherein the heat transfer portion may include a first base layer disposed on the electronic component, a coating layer disposed on the first base layer, a heat dissipating material disposed on the coating layer and chemically bonded to the coating layer, and a second base layer disposed on the heat dissipating material.

### CROSS-REFERENCE TO RELATED APPLICATIONS

This application is a continuation of International Application No. PCT/KR2025/010297 designating the United States, filed on Jul. 14, 2025, in the Korean Intellectual Property Receiving Office and claiming priority to Korean Patent Application Nos. 10-2024-0099262, filed on Jul. 26, 2024, and 10-2024-0122638, filed on Sep. 9, 2024, in the Korean Intellectual Property Office, the disclosures of each of which are incorporated by reference herein in their entireties.

### BACKGROUND

### Field

The disclosure relates to an electronic device and, for example, to an electronic device including a heat transfer portion.

### Description of Related Art

With the remarkable advancements in information and communication technology, as well as semiconductor technology, the distribution and use of various electronic devices have rapidly increased. In particular, recent electronic devices have been developed to enable portability and communication capabilities.

Electronic devices may refer to a device that performs specific functions based on embedded programs such as home appliances, electronic notes, portable multimedia players (PMPs), mobile communication terminals, tablet personal computers (PCs), video/audio devices, desktop/laptop computers, vehicle navigation systems, and so forth. For instance, these electronic devices may output stored information in the form of audio or video. With the increasing integration of electronic devices and the common use of ultra-high-speed and large-volume wireless communication, various functions have recently come to be provided in a single electronic device, such as a mobile communication terminal. For example, various functions such as an entertainment function such as gaming, a multimedia function such as music/video playback, a communication and security function for mobile banking, and/or a function such as a schedule management or electronic wallet, as well as a communication function have been integrated into a single electronic device.

The above-described information may be provided as background art to aid in understanding the disclosure. No assertion or decisions are made regarding whether any of the above-described contents can be applied as prior art related to the disclosure.

### SUMMARY

According to an example embodiment of the disclosure, an electronic device may be provided. According to an embodiment, the electronic device may include: a housing; a board assembly disposed inside the housing, wherein the board assembly includes a printed circuit board having a first surface and a second surface; an electronic component disposed on the first surface of the board assembly; a shielding portion comprising a shielding material disposed on the first surface and surrounding at least a portion of the electronic component, wherein the shielding portion includes a first support portion forming a receiving space and a shielding sheet covering at least a portion of the receiving space, and a heat transfer portion disposed between the electronic component and the shielding sheet and configured to exchange heat with the electronic component, wherein the heat transfer portion includes a first base layer disposed on the electronic component, a coating layer disposed on the first base layer, a heat dissipating material disposed on the coating layer and chemically bonded to the coating layer, and a second base layer disposed on the heat dissipating material.

According to an example embodiment of the disclosure, a heat transfer portion may be provided. According to an embodiment, the heat transfer portion may include: a first base layer, a coating layer disposed on the first base layer, a heat dissipating material disposed on the coating layer and chemically bonded to the coating layer, and a second base layer disposed on the heat dissipating material.

According to an example embodiment of the disclosure, a method of manufacturing may be provided. According to an example embodiment, the method of manufacturing the heat transfer portion may include: forming a first base layer, coating a coating layer on the first base layer, applying a liquid heat dissipating material to the coating layer, and laminating a second base layer with the heat dissipating material and the coating layer, wherein the coating layer and the heat dissipating material are chemically bonded.

### BRIEF DESCRIPTION OF THE DRAWINGS

The above and other aspects, features and advantages of various embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a front perspective view illustrating an example electronic device according to various embodiments;

FIG. 3 is a rear perspective view illustrating an example electronic device according to various embodiments;

FIG. 4 is an exploded perspective view illustrating the front side of an electronic device according to various embodiments;

FIG. 5 is a cross-sectional view of a heat transfer portion according to various embodiments;

FIG. 6A is a cross-sectional view illustrating a portion of the board assembly of the electronic device, taken along line A-A′ of FIG. 4, according to various embodiments;

FIG. 6B is a cross-sectional view illustrating a portion of the board assembly of the electronic device, taken along line A-A′ of FIG. 4, according to various embodiments;

FIG. 6C is a cross-sectional view illustrating a portion of the board assembly of the electronic device, taken along line A-A′ of FIG. 4, according to various embodiments;

FIG. 7 is a diagram illustrating an example process of forming a heat transfer portion with an encapsulation structure according to various embodiments;

FIG. 8A is a diagram illustrating example bonding between a base layer and a coating layer according to various embodiments;

FIG. 8B is a diagram illustrating an example chemical composition of the base layer according to various embodiments;

FIG. 9A is a diagram illustrating an example chemical composition of the coating layer according to various embodiments;

FIG. 9B is a diagram illustrating an example monomer unit of the coating layer 330 of FIG. 9A according to various embodiments;

FIG. 10A is a diagram illustrating example bonding between the coating layer and the first base layer and the bonding between the coating layer and the heat dissipating material according to various embodiments;

FIG. 10B is a diagram illustrating example bonding between the coating layer and the first base layer and the bonding between the coating layer and the heat dissipating material according to various embodiments;

FIG. 11 is a diagram illustrating a comparative example according to various embodiments;

FIG. 12 is a cross-sectional view illustrating a comparative example according to various embodiments;

FIG. 13A is a cross-sectional view of a heat transfer portion with an opening formed therein according to various embodiments;

FIG. 13B is a cross-sectional view of a heat transfer portion with an opening formed therein according to various embodiments;

FIG. 14 is a cross-sectional view of a heat transfer portion with filler particles filled in a base layer according to various embodiments;

FIG. 15A is a perspective view of a heat transfer portion with an encapsulation structure according to various embodiments;

FIG. 15B is a cross-sectional view of a heat transfer portion according to a comparative example compared to the encapsulation structure, according to various embodiments;

FIG. 16A is a perspective view illustrating a heat transfer portion according to various embodiments;

FIG. 16B is a perspective view illustrating a heat transfer portion in which a plurality of heat dissipation materials are formed to be spaced apart, according to various embodiments;

FIG. 17A is a diagram illustrating an example process of forming a heat transfer portion in a case where the first base layer is flat according to various embodiments;

FIG. 17B is a diagram illustrating an example process of forming a heat transfer portion in a case where the first base layer is concave according to various embodiments; and

FIG. 17C is a diagram illustrating an example process of forming a heat transfer portion in a case where the first base layer is convex according to various embodiments.

Throughout the accompanying drawings, like reference numerals may be assigned to like parts, components, and/or structures.

### DETAILED DESCRIPTION

An electronic device generates heat during operation, and if this heat accumulates within the device, it may degrade the performance of the electronic device or even cause damage. Therefore, the presence of a heat transfer portion to maintain the temperature of the electronic device is essential to ensure thermal management and stability.

As the performance of the heat transfer portion improves, the performance of the electronic device can be optimized, playing a crucial role in extending the device's lifespan. As a result, ongoing efforts are being made to develop heat transfer portions with superior performance to support higher performance and greater stability in electronic devices.

The following description taken in conjunction with the accompanying drawings may be presented to provide a comprehensive understanding of various example implementations of the disclosure. The various example embodiments disclosed in the following description entail various specific details to aid understanding, but are regarded as one of various embodiments. Accordingly, it will be apparent to those skilled in the art that various changes and modifications may be made to the various implementations described in the disclosure without departing from the scope and spirit of the disclosure. Further, descriptions of well-known functions and configurations may be omitted for clarity and brevity.

The terms and words used in the following description and claims are not limited to the bibliographical meaning, but may be used to clearly and consistently describe the various embodiments of the disclosure. Therefore, it will be apparent to those skilled in the art that the following description of various implementations of the disclosure is provided only for the purpose of description, not for the purpose of limiting the disclosure.

The singular forms “a,” “an,” and “the” are intended to include the plural forms as well, unless the context clearly indicates otherwise. Thus, as an example, “a component surface” may be interpreted as including one or more of the surfaces of a component.

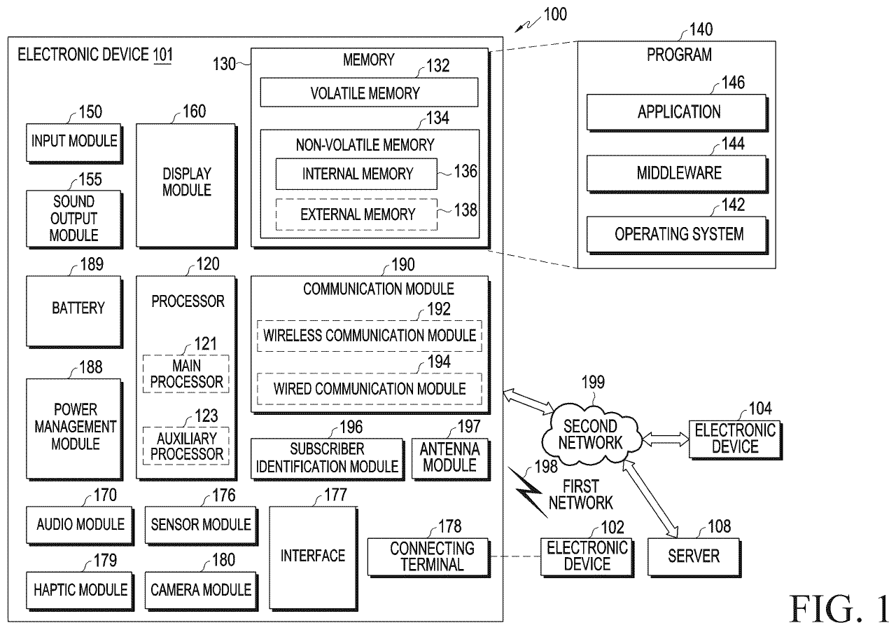

FIG. 1 is a block diagram illustrating an example electronic device in a network environment 100 according to various embodiments of the disclosure.

Referring to FIG. 1, the electronic device 101 in the network environment 100 may communicate with an external electronic device 102 via a first network 198 (e.g., a short-range wireless communication network), or an external electronic device 104 or a server 108 via a second network 199 (e.g., a long-range wireless communication network). According to an embodiment, the electronic device 101 may communicate with the external electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. In an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a second sensor module configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., external electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the external electronic device 102) directly (e.g., wiredly) or wirelessly. According to an embodiment, the interface 177 may include, for example, a high-definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the external electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the external electronic device 102, the external electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the external electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IOT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

The electronic device according to an embodiment of the disclosure may be one of various types of devices. The electronic devices may include, for example, a portable communication device (e.g., a smartphone), a computer device, a portable multimedia device, a portable medical device, a camera, a wearable device, a home appliance, or the like. The electronic devices according to an embodiment are not limited to those described above.

It should be appreciated that various example embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

An embodiment of the disclosure may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The storage medium readable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or further, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

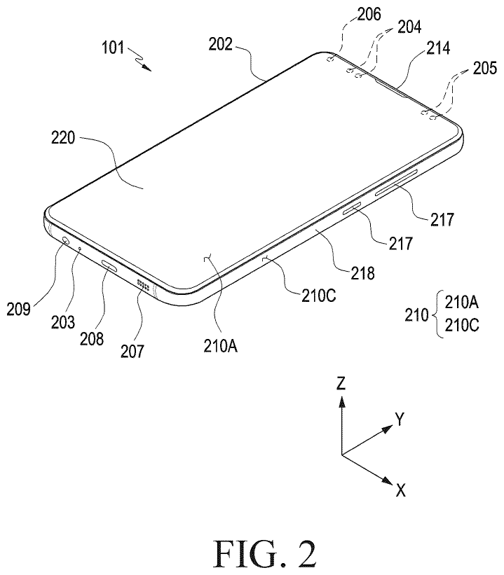

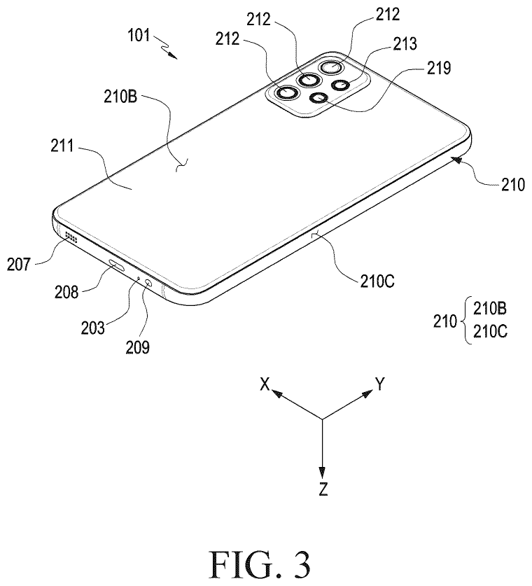

FIG. 2 is a front perspective view illustrating the front surface 210A of an electronic device 101 according to various embodiments. FIG. 3 is a rear perspective view illustrating the rear surface 210B of an electronic device 101 according to various embodiments.

In FIGS. 2, 3, and the following detailed description, the length direction of the electronic device 100 may be defined as the “Y-axis direction”, the width direction as the “X-axis direction”, and/or the height (or thickness) direction as the “Z-axis direction”. In the following detailed description, references to the length direction, width direction, and/or height direction (or thickness direction) may indicate the respective length, width, and/or height (or thickness) direction of the electronic device 100. In various embodiments, both the orthogonal coordinate system illustrated in the drawings and “negative/positive (−/+)” directions may be referred to regarding the direction in which an element is oriented. According to an embodiment, the arrangement relationship of elements in the height direction, e.g., the reference of “above/below”, may follow the Z-axis direction. Specifically, when it is stated that one element is disposed above another element, this may indicate that the element is positioned along the Z-axis direction relative to the other element. Conversely, when it is stated that one element is disposed below another element, this may indicate that the element is positioned along a direction opposite to the Z-axis relative to the other element. It should be noted that even if one element is disposed above or below another element, this does not necessarily mean that the entirety of the element is positioned above or below the entirety of the other element. For example, one portion of an element may be positioned above a portion of another element, while another portion of the same element may be positioned below another portion of the other element. In the following description, when an element is described as being overlapped (or stacked) with another element, the aforementioned explanation of the arrangement relationship in the height direction may apply. In describing directions, if the “negative/positive (−/+)” direction is not specified, it may be interpreted as facing the positive direction unless otherwise defined. For example, the “Z-axis direction” may be interpreted as facing the +Z direction, the “X-axis direction” as facing the +X direction, and the “Y-axis direction” as facing the +Y direction. In addition, describing a direction as facing any of the three axes of an orthogonal coordinate system may include a direction parallel to the corresponding axis. According to an embodiment of the disclosure, the “X-axis direction” may be referred to as the “first direction”, and the “Z-axis direction” may be referred to as the “second direction”. It should be noted that this is based on the orthogonal coordinate system described in the drawings for the sake of brevity, and such descriptions of directions or elements do not limit the various embodiments of the disclosure.

Referring to FIGS. 2 and 3, an electronic device 101 according to an embodiment of the disclosure may include a first surface (or front surface) 210A, a second surface (or rear surface) 210B, and a third surface (or side surface) 210C surrounding a space between the first surface 210A and the second surface 210B.

According to an embodiment of the disclosure, at least a portion of the first surface 210A may be formed by a substantially transparent front plate 202 (e.g., a glass plate or polymer plate including various coating layers). The second surface 210B may be formed by a substantially opaque rear plate 211. The rear plate 211 may be formed of, for example, coated or colored glass, ceramic, polymer, metal (e.g., aluminum, stainless steel (STS), or magnesium), or a combination of at least two of these materials. The side surface 210C may be formed by a side structure 218 (or “side bezel structure”) that couples to the front plate 202 and the rear plate 211 and includes metal and/or polymer. In an embodiment, the rear plate 211 and the side structure 218 may be integrally formed and may include the same material (e.g., a metal material such as aluminum).

According to an embodiment of the disclosure, an electronic device 101 may include at least one or more of a display 220, an audio module 203, 207, 214, a sensor module 204, 219, a camera module 205, 212, 213, a key input device 217, a light-emitting element 206, and connector holes 208, 209. In an embodiment, the electronic device 101 may omit at least one of components (e.g., the key input device 217 or the light-emitting element 206) or additionally include other components.

According to an embodiment of the disclosure, a display 220 may be visible through a substantial portion of the front plate 202. In an embodiment, at least a portion of the display 220 may be visible through the front plate 202 forming the first surface 210A or through a portion of the side surface 210C. In an embodiment, the edges of the display 220 may be formed to be substantially the same as the adjacent outer shape of the front plate 202.

According to an embodiment of the disclosure (not shown), a recess or an opening may be formed in a portion of the screen display area of the display 220, and the electronic device may include at least one or more of an audio module 214, a sensor module 204, a camera module 205, and a light-emitting element 206 aligned with the recess or the opening. According to an embodiment of the disclosure (not shown), the rear side of the screen display area of the display 220 may include at least one or more of an audio module 214, a sensor module 204, a camera module 205, a fingerprint sensor (not shown), and a light-emitting element 206. According to an embodiment of the disclosure (not shown), the display 220 may be coupled with or arranged adjacent to a touch detection circuit, a pressure sensor capable of measuring the intensity (pressure) of a touch, and/or a digitizer for detecting a magnetic stylus pen.

According to an embodiment of the disclosure, an audio module 203, 207, 214 may include a microphone hole 203 and speaker holes 207, 214. The microphone hole 203 may have a microphone disposed inside to obtain external sound, and in an embodiment, a plurality of microphones may be arranged to detect the direction of sound. The speaker holes 207, 214 may include an external speaker hole 207 and a receiver hole 214 for calls. In an embodiment, the speaker holes 207, 214 and the microphone hole 203 may be implemented as a single hole, or a speaker may be included without the speaker holes 207, 214 (e.g., a piezo speaker).

According to an embodiment of the disclosure, a sensor module 204, 219 may generate electrical signals or data values corresponding to the operational state inside the electronic device 101 or the environmental conditions outside the electronic device. The sensor module 204, 219 may include, for example, a first sensor module 204 (e.g., a proximity sensor) and/or a second sensor module (not shown) (e.g., a fingerprint sensor) disposed on the first surface 210A of the housing 210, and/or a third sensor module 219 and/or a fourth sensor module (e.g., a fingerprint sensor) disposed on the second surface 210B of the housing 210. The fingerprint sensor may be disposed not only on the first surface 210A of the housing 210 (e.g., the display 220) but also on the second surface 210B or the side surface 210C. The electronic device 101 may further include at least one of a gesture sensor, a gyro sensor, a pressure sensor, a magnetic sensor, an accelerometer, a grip sensor, a color sensor, an IR (infrared) sensor, a bio-sensor, a temperature sensor, a humidity sensor, or an illuminance sensor.

According to an embodiment of the disclosure, a camera module 205, 212, 213 may include a first camera device 205 disposed on the first surface 210A of the electronic device 101, a second camera device 212 disposed on the second surface 210B, and/or a flash 213. The camera devices 205, 212 may include one or more lenses, an image sensor, and/or an image signal processor. The flash 213 may include, for example, a light-emitting diode (LED) or a xenon lamp. In an embodiment, two or more lenses (e.g., an infrared camera, wide-angle lens, and telephoto lens) and image sensors may be disposed on a single surface of the electronic device 101. In an embodiment, the flash 213 may emit infrared light, and the infrared light emitted by the flash 213 and reflected by a subject may be received through the third sensor module 219. The electronic device 101 or a processor of the electronic device 101 may detect depth information of the subject based on the time at which the infrared light is received by the third sensor module 219.

According to an embodiment of the disclosure, a key input device 217 may be disposed on the side surface 210C of the housing 210. In an embodiment, the electronic device 101 may not include some or all of the aforementioned key input devices 217, and the excluded key input device 217 may be implemented in other forms, such as a soft key, on the display 220. In an embodiment, the key input device may include a sensor module disposed on the second surface 210B of the housing 210.

According to an embodiment of the disclosure, a light-emitting element 206 may be disposed, for example, on the first surface 210A of the housing 210. The light-emitting element 206 may provide, for example, status information of the electronic device 101 in the form of light. In an embodiment, the light-emitting element 206 may provide a light source interlinked with the operation of the camera module 205. The light-emitting element 206 may include, for example, an LED, an IR LED, and a xenon lamp.

The connector holes 208, 209 may include a first connector hole 208 configured to accommodate a connector (e.g., a USB connector) for transmitting and/or receiving power and/or data to and from an external electronic device, and/or a second connector hole 209 configured to accommodate a connector (e.g., an earphone jack) for transmitting and/or receiving audio signals to and from an external electronic device.

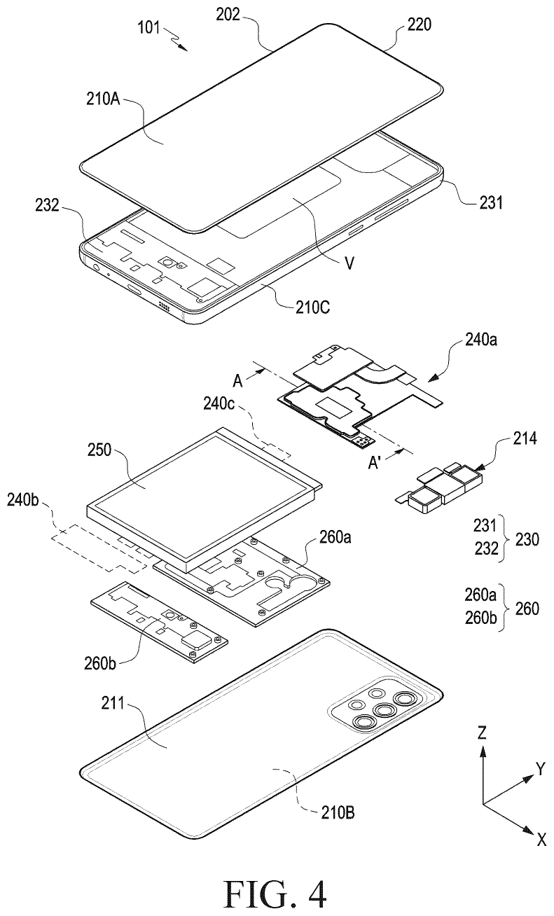

FIG. 4 is an exploded perspective view illustrating the front side of an electronic device 101 according to various embodiments.

Referring to FIG. 4, the electronic device 101 according to an embodiment of the disclosure may include a side structure 231, a first support portion 232 (e.g., a bracket), a display 220, at least one printed circuit board 240a, 240b (or board assembly), a battery 250, a second support portion 260, an antenna, a camera assembly 214, and a rear plate 211. When a plurality of printed circuit boards 240a, 240b are included, the electronic device 101 may include at least one flexible printed circuit board 240c to electrically connect the different printed circuit boards. For example, the printed circuit boards 240a, 240b may include a first board assembly 240a disposed on one side (e.g., the upper side or the Y-direction) of the battery 250 and a second board assembly 240b disposed on the other side (e.g., the lower side or the-Y direction) of the battery 250. The first board assembly 240a and the second board assembly 240b may be electrically connected by the flexible printed circuit board 240c.

According to an embodiment of the disclosure, the first support portion 232 may be provided in at least a partially flat plate shape. In an embodiment, the first support portion 232 may be disposed inside the electronic device 101 and may be connected to the side structure 231 or formed integrally with the side structure 231. The first support portion 232 may be formed of, for example, a metal material and/or a non-metal material (e.g., a polymer). When the first support portion 232 is formed at least partially of a metal material, a portion of the side structure 231 or the first support portion 232 may function as an antenna. The first support portion 232 may have a display 220 coupled to one surface (e.g., in the Z direction) and a board assembly 240a, 240b coupled to the opposite surface (e.g., in the-Z direction). The board assembly 240a, 240b may include, for example, an interposer, a processor, memory, and/or an interface. The processor may include, for example, one or more of a central processing unit (CPU), application processor (AP), graphics processing unit (GPU), image signal processor (ISP), sensor hub processor, or communication processor.

According to an embodiment of the disclosure, the front plate 202 may be coupled to the support portion 232 through an adhesive member including an adhesive. The front plate 202 may also be referred to as a “cover” or “front cover”. The rear plate 211 may also be referred to as a “cover” or “rear cover”. The edge of the rear cover 211 may be supported by the support portion 232.

According to an embodiment of the disclosure, the combination of the first support portion 232 and the side structure 231 may be referred to as a front case or a housing 230. The housing 230 may also be referred to as a frame 230. According to an embodiment, the housing 230 may accommodate a board assembly 240a, 240b or a battery 250.

According to an embodiment of the disclosure, the housing 230 may form at least a portion of the exterior of the electronic device 101. The housing 230 may include a side structure 231, a first support portion 232, a front plate 202, and a rear plate 211. In an embodiment of the disclosure, the term “front or rear of the housing 230” may refer to the front plate 202 or the rear cover 211. In an embodiment, the first support portion 232 may be disposed between the front plate 202 and the rear plate 211 and may function as a structure for accommodating electrical/electronic components, such as a board assembly 240a, 240b or a camera assembly 214.

According to an embodiment of the disclosure, the interface may include, for example, an HDMI (high-definition multimedia interface), a USB (universal serial bus) interface, an SD card interface, and/or an audio interface. The interface may electrically or physically connect the electronic device 101 to an external electronic device and may include a USB connector, an SD card/MMC connector, or an audio connector.

According to an embodiment of the disclosure, the second support portion 260 may include, for example, an upper support portion 260a and a lower support portion 260b. In an embodiment, the upper support portion 260a may be disposed to surround the board assembly 240a, 240b (e.g., the first board assembly 240a) together with a portion of the first support portion 232. For example, the upper support portion 260a of the second support portion 260 may be disposed to face the first support portion 232 with the first board assembly 240a positioned between them.

According to an embodiment of the disclosure, the lower support portion 260b of the second support portion 260 may be disposed to face the first support portion 232 with the second board assembly 240b positioned between them. Circuit devices (for example, a processor, communication module, or memory) implemented in the form of an integrated circuit chip, as well as various electrical/electronic components, may be arranged on the printed circuit boards 240a, 240b. Depending on the embodiment, the printed circuit boards 240a, 240b may be provided with an electromagnetic shielding environment by the second support portion 260. In an embodiment, the lower support portion 260b may function as a structure for accommodating electrical/electronic components such as a speaker module or interfaces (e.g., a USB connector, an SD card/MMC connector, or an audio connector).

In an embodiment of the disclosure, electrical/electronic components such as a speaker module and an interface (e.g., a USB connector, an SD card/MMC connector, or an audio connector) may be disposed on an additional printed circuit board, which is not shown. For example, the lower support portion 260b may be arranged to surround the additional printed circuit board together with another portion of the first support portion 232.

According to an embodiment of the disclosure, the battery 250 may be a device for supplying power to at least one component of the electronic device 101 and may include, for example, a non-rechargeable primary battery, a rechargeable secondary battery, or a fuel cell. At least a portion of the battery 250 may be arranged, for example, on substantially the same plane as the printed circuit boards 240a, 240b. The battery 250 may be integrally disposed inside the electronic device 101 or may be detachably mounted to the electronic device 101.

Although not shown, the antenna may include, for example, a conductive pattern implemented on the surface of the second support portion 260 through a laser direct structuring (LDS) process. In an embodiment, the antenna may include a printed circuit pattern formed on the surface of a thin film, and the thin-film antenna may be disposed between the rear plate 211 and the battery 250. The antenna may include, for example, an NFC (near field communication) antenna, a wireless charging antenna, and/or an MST (magnetic secure transmission) antenna. The antenna may perform, for example, near-field communication with an external device or wirelessly transmit and receive power for charging. In an embodiment, another antenna structure may be formed by a portion of the side structure 231 and/or a portion of the first support portion 232 or a combination thereof.

According to an embodiment of the disclosure, the electronic device 101 may include a heat dispersion portion V. For example, the heat dispersion portion V may be disposed on the first support portion 232. Heat generated inside the electronic device 101 may be dispersed through the heat dispersion portion V or emitted to the outside of the electronic device 101. For instance, heat generated by the first board assembly 240a may be transferred toward the battery 250 through the heat dispersion portion. The heat dispersion portion may include, for example, a vapor chamber or a heat pipe.

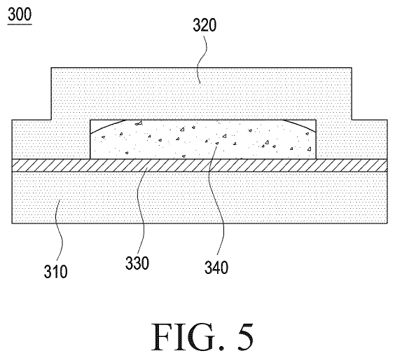

Hereinafter, with reference to FIGS. 5 to 17, each component included in the electronic device 101 will be described in greater detail.

FIG. 5 is a cross-sectional view of a heat transfer portion 300 according to various embodiments.

The heat transfer portion 300 described with reference to FIGS. 5 to 16 may be included in the board assembly 240a described with reference to FIG. 3.

Referring to FIG. 5, the heat transfer portion 300 may include base layers 310, 320 (e.g., paraffin wax), a coating layer 330 (e.g., polydopamine (PDA)), and a heat dissipating material 340 (e.g., gallium (Ga)).

According to an embodiment of the disclosure, the heat transfer portion 300 may include a first base layer 310 disposed on an electronic component 241, which will be described later; a coating layer 330 disposed on the first base layer 310; a heat dissipating material 340, which is chemically bonded to the coating layer 330 and is liquid at room temperature, disposed on the coating layer 330; and a second base layer 320 disposed on the heat dissipating material 340.

According to an embodiment, room temperature refers to indoor temperature and may indicate a temperature of approximately 15° C. to 25° C. However, in this disclosure, an example is described in which the heat dissipating material 340 is liquid at room temperature, while the first base layer 310 and the second base layer 320, which surround the heat dissipating material 340, are solid at room temperature. However, the heat dissipating material 340 is not limited to being in a liquid state only at room temperature and may also be characterized by being in a liquid state when the heat transfer portion 300 transfers heat and/or when the heat transfer portion 300 is manufactured.

According to an embodiment, since the heat dissipating material 340 is in a liquid state, the heat dissipating material 340 may exhibit fluidity. In addition, due to its liquid state, the heat dissipating material 340 may leak to the outside of the heat transfer portion 300. If the heat dissipating material 340 leaks, the leaked heat dissipating material 340 may cause malfunction and/or contamination of the electronic device 101.

According to an embodiment, in order to prevent and/or reduce malfunction and/or contamination of the electronic device 101, the heat transfer portion 300 may be formed in an encapsulating structure in which the base layers 310 and 320 for controlling the fluidity of the heat dissipating material 340 surround the heat dissipating material 340.

According to an embodiment of the disclosure, to control the fluidity of the liquid heat dissipating material 340, the heat transfer portion 300 may be implemented in an encapsulating structure in which the base layers 310 and 320 surround the heat dissipating material 340. To further enhance the control of fluidity, the coating layer 330 and the heat dissipating material 340 and/or the coating layer 330 and the base layers 310 and 320 may be chemically bonded to each other.

When the fluidity of the heat dissipating material 340 is controlled through the encapsulation structure and chemical bonding, an electronic device 101 may be provided that exhibits excellent heat dissipation performance using a liquid heat dissipating material 340 with high thermal conductivity while preventing/reducing malfunction and/or contamination that may occur due to leakage of the heat dissipating material 340.

The bond between the coating layer 330 and the base layers 310, 320 may be, for example, a covalent bond, which is a type of chemical bond formed by atoms sharing electrons. According to an embodiment, the bond between the coating layer 330 and the base layers 310, 320 may be a coordinative bond, which is a type of covalent bond in which only one of the two chemically bonded atoms donates the electrons. A coordinative bond is formed between a central metal ion and a ligand containing an electron pair, wherein the metal ion accepts the electron pair from the ligand to form a coordination compound.

The chemical bond between the coating layer 330 and the heat dissipating material 340 may also be a covalent bond. According to an embodiment, the chemical bond between the coating layer 330 and the heat dissipating material 340 may be a hydrogen bond, in which a highly electronegative atom such as nitrogen, oxygen, or fluorine shares an electron pair with hydrogen to form a chemical bond.

Generally, since a hydrogen bond is a covalent bond between a highly electronegative atom, such as nitrogen, oxygen, or fluorine, and a highly electronegative hydrogen atom, it may form a stronger chemical bond than a typical covalent bond. According to an embodiment, since the chemical bond between the coating layer 330 and the heat dissipating material 340 is a hydrogen bond, the coating layer 330 may more effectively control the fluidity of the heat dissipating material 340.

According to an embodiment, since the coating layer 330 forms strong chemical bonds with the base layers 310, 320 and/or the heat dissipating material 340, the coating layer 330 in the heat transfer portion 300 may serve to adhere the heat dissipating material 340 to the base layers 310, 320 and/or to the coating layer 330.

The particles of the base layers 310, 320 may generally have weak surface bonding force, which refers to the chemical bonding force generated by contact with other materials. Therefore, if a coating layer 330, which has adhesive properties, is disposed between the first base layer 310 and the second base layer 320, the surface bonding force between the base layers 310, 320 may be enhanced.

According to an embodiment, the coating layer 330 may be disposed between the first base layer 310 and the second base layer 320 to enhance the bonding force between the first base layer 310 and the second base layer 320. Additionally, an encapsulation structure may be formed using the first base layer 310 and the second base layer 320 to control the fluidity of the heat dissipating material 340. Through this structure, leakage of the heat dissipating material 340 to the outside from between the base layers 310, 320 may be prevented and/or reduced.

According to an embodiment, while the base layers 310, 320 are described as comprising paraffin wax by way of example in this disclosure and the following embodiments, they are not limited thereto and may include various types of base layer particles, which will be described later.

The first base layer 310 and the second base layer 320 are illustrated as including the same type of particles. However, the first base layer 310 and the second base layer 320 may also include different types of base layer particles, which will be described in greater detail below.

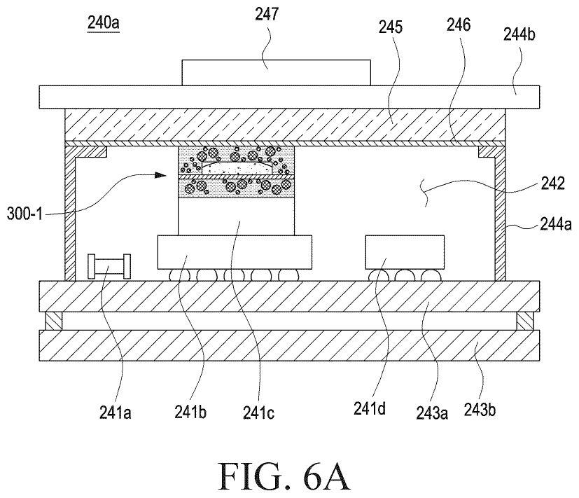

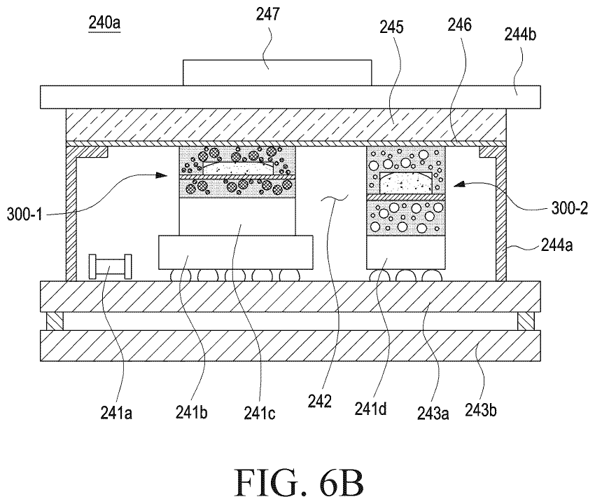

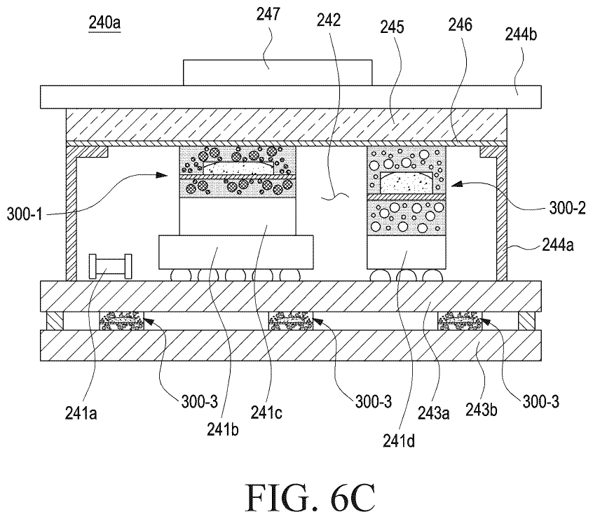

FIGS. 6A, 6B, and 6C are cross-sectional views of a board assembly 240a, taken along line A-A′ shown in FIG. 4 according to various embodiments.

Referring to FIGS. 6A, 6B and 6C (which may be referred to as FIGS. 6A to 6C), the board assembly according to an embodiment of the disclosure may be included in the board assembly 240a described with reference to FIG. 3.

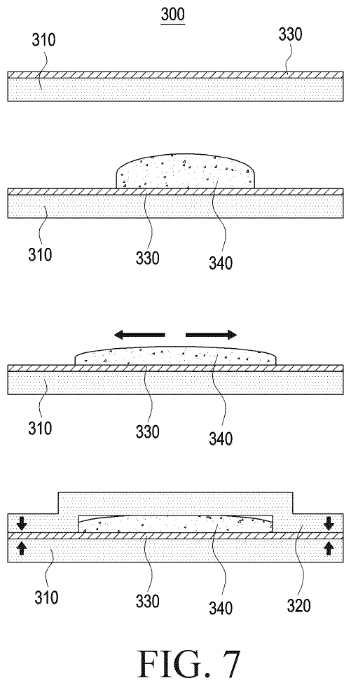

FIGS. 6A to 6C are conceptual diagrams illustrating the internal structure of the board assembly 240a. FIGS. 6A to 6C may illustrate the internal structure of the board assembly 240a at a moment during its assembly process. The components described with reference to FIGS. 6A to 6C may be partially or entirely the same as the components described with reference to FIGS. 1 to 5. The components described with reference to FIGS. 6A to 6C may be partially or entirely the same as the components described in greater detail below with reference to FIGS. 7 to 17.

According to an embodiment, the board assembly 240a may include a printed circuit board 243, and the printed circuit board 243 may include a first surface 243a and a second surface 243b.

According to an embodiment, electronic components 241a, 241b, 241c, and 241d and/or a first support portion 244a may be disposed on the first surface 243a of the printed circuit board 243.

According to an embodiment, the electronic components 241a, 241b, 241c, and 241d may include a second electronic component 241b and a third electronic component 241c, which serve as main heat sources (e.g., a DRAM and an application processor (AP)), and a first electronic component 241a and a fourth electronic component 241d, which serve as other heat sources (e.g., a power management integrated circuit (PMIC) and a charge IC).

According to an embodiment, the second electronic component 241b and/or the third electronic component 241c, which are main heat sources, may generate a greater amount of heat than the first electronic component 241a and the fourth electronic component 241d, which are other heat sources. Accordingly, referring to FIG. 6A, a heat transfer portion 300 may be disposed on the third electronic component 241c, which is a main heat source, to effectively transfer heat to the outside.

According to an embodiment, the board assembly 240a may include a shielding portion. The shielding portion may include a first support portion 244a and a shielding sheet 246. The first support portion 244a may be coupled to the printed circuit board 243a. The first support portion 244a and the shielding sheet 246 may surround the electronic components 241a, 241b, 241c, and 241d. The first support portion 244a and the shielding sheet 246 may shield electromagnetic waves generated by the electronic components 241a, 241b, 241c, and 241d, thereby preventing/reducing malfunction of the electronic device 101 due to electromagnetic leakage.

According to an embodiment, the receiving space 242 may be a space surrounded by the first support portion 244a and the shielding sheet 246 and may be a space in which the electronic components 241a, 241b, 241c, and 241d are disposed.

According to an embodiment, a second support portion 244b may be disposed on the first support portion 244a. According to an embodiment, a first heat dissipation portion 245 and a shielding sheet 246 may be disposed on the first support portion 244a, and the second support portion 244b may be disposed on the first heat dissipation portion 245.

According to an embodiment, the second support portion 244b may seal the receiving space 242 formed inside the first support portion 244a. The second support portion 244b may cover the electronic components 241a, 241b, 241c, and 241d disposed inside the first support portion 244a.

A second heat dissipation portion 247 may be disposed on the second support portion 244b and may transfer heat generated by the electronic components 241a, 241b, 241c, and 241d to the outside.

Referring to FIGS. 6A to 6C, the heat transfer portion 300 may be disposed on the electronic components 241a, 241b, 241c, and 241d and/or between the first surface 243a and the second surface 243b of the printed circuit board 243.

Referring to FIG. 6A, a heat transfer portion 300-1 may be disposed on the third electronic component 241c, which is a main heat source. When the heat transfer portion 300 is disposed on the third electronic component 241c, heat generated by the second electronic component 241b and/or the third electronic component 241c may be transferred to the outside of the board assembly 240a through the heat transfer portion 300-1. As a result, overheating inside the electronic device 101 due to heat generation may be mitigated.

Referring to FIG. 6B, to further improve heat dissipation in the electronic device 101, heat transfer portions 300-1 and 300-2 may be disposed not only on the third electronic component 241c, which is a main heat source, but also on the fourth electronic component 241d, which is another heat source. According to an embodiment, although the disclosure describes an example in which the heat transfer portions 300-1 and 300-2 are disposed on the third electronic component 241c and the fourth electronic component 241d, the disclosure is not limited thereto, and the heat transfer portions may be disposed on all of the electronic components 241a, 241b, 241c, and 241d disposed inside the board assembly 240a.

As a result, the heat transfer portions 300-1 and 300-2 may more effectively transfer heat from inside the board assembly 240a to the outside. According to an embodiment, overheating inside the electronic device 101 due to heat generation may be more effectively mitigated when the heat transfer portions 300-1 and 300-2 are disposed on both the third electronic component 241c and the fourth electronic component 241d, compared to a case where only the heat transfer portion 300-1 is disposed on the third electronic component 241c, which is a main heat source.

Furthermore, referring to FIG. 6C, to maximize and/or increase the heat dissipation effect of the electronic device 101, the heat transfer portions 300-1, 300-2, and 300-3 may be disposed not only on the electronic components 241a, 241b, 241c, and 241d but also at other locations inside the printed circuit board. For example, the heat transfer portion 300-3 may be disposed between the first surface 243a and the second surface 243b of the printed circuit board 243.

According to an embodiment, the placement of the heat transfer portion 300 in the disclosure may be determined based on the heat dissipation performance required by the electronic device 101, using various embodiments disclosed in FIG. 6 or a combination thereof. The placement of the heat transfer portion 300 is not limited to the illustrated examples, and the heat transfer portion 300 may be disposed at any location inside the electronic device 101 where heat dissipation is required.

FIG. 7 is a diagram illustrating an example process of forming a heat transfer portion 300 having an encapsulation structure according to various embodiments.

Referring to FIG. 7, to form the heat transfer portion 300, a coating layer 330 having a high surface bonding force may be disposed on a first base layer 310, and a heat dissipating material 340 may be disposed on the coating layer 330.

Even when the heat dissipating material 340 is disposed on the coating layer 330, the heat dissipating material 340 may move on the coating layer 330 due to its fluidity. Accordingly, after the heat dissipating material 340 is disposed on the coating layer 330, a second base layer 320 may be disposed to surround the heat dissipating material 340 before the heat dissipating material 340 flows out of the coating layer 330.

Through the above-described placement process, by disposing the coating layer 330, which has a high surface bonding force, between the first base layer 310 and the second base layer 320, a chemical bond may be formed between the coating layer 330 and the base layers 310 and 320 and/or between the coating layer 330 and the heat dissipating material 340.

As a result, the bonding force between the first base layer 310 and the second base layer 320 may be greater than a case where the coating layer 330 is absent between the first base layer 310 and the second base layer 320, thereby enabling control of the fluidity of the heat dissipating material 340.

According to an embodiment, after solidifying a solution of, for example, paraffin wax, which forms the first base layer 310, at room temperature, a coating layer 330 may be coated on the first base layer 310. After coating the coating layer 330, the coating layer 330 may be dried at room temperature for a predetermined time (e.g., 24 hours), and the heat dissipating material 340 may be disposed on the coating layer 330. The second base layer 320 may then be disposed on the heat dissipating material 340, and heat may be applied to the edges of the second base layer 320 (e.g., at a temperature of approximately 80° C. to 100° C. for about one minute) to press the first base layer 310 and the second base layer 320 together, thereby forming the heat transfer portion 300.

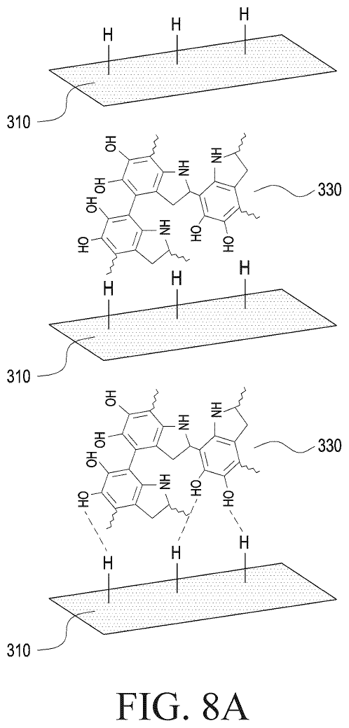

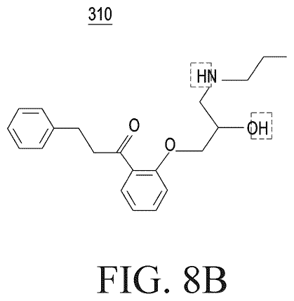

FIG. 8A is a diagram illustrating the example bond between the base layers 310 and 320 and the coating layer 330 according to various embodiments. FIG. 8B is a diagram illustrating an example chemical structure of the base layers 310 and 320 according to various embodiments.

Referring to FIGS. 8A and 8B, a chemical bond may be formed between hydrogen functional groups (—H) formed on the outer surfaces of the base layers 310 and 320 and hydroxyl groups (—OH) of the coating layer 330. According to an embodiment, when the coating layer 330 is coated on the base layers 310 and 320 that include hydrogen functional groups (—H), a chemical bond may be induced between the hydrogen functional groups (—H) of the base layer 310 and the hydroxyl groups (—OH) of the coating layer 330. The chemical bond may be hydrogen bonding. In the disclosure and the following embodiments, as an example of a case where

the functional groups of the base layers 310 and 320 are hydrogen functional groups (—H) and the functional groups of the coating layer 330 are hydroxyl groups (—OH), the chemical bond between the base layers 310 and 320 and the coating layer 330 is described as hydrogen bonding. However, the disclosure is not limited thereto. Depending on the various components of the base layers 310 and 320 and the various functional groups of the coating layer 330, which will be described later, the base layers 310 and 320 and the coating layer 330 may form various types of chemical bonds. Since the coating layer 330 may include various functional groups, as will be described later, it may chemically bond to the base layers 310 and 320.

The following table categorizes materials capable of phase change at specific temperatures, which may be used for the base layers 310 and 320, according to their elements. As shown in the table below, such phase-changeable materials may include paraffin, hydrated salts, and the like.

TABLE 1

| | Melting | Latent Heat | Thermal |
|---|---|---|---|
| | Point | of Fusion | Conductivity |
| Element | (° C.) | (kJ/mol) | (W/(m · K)) |
| Dimethyl-sulfoxide | 16.5 | 85.7 | N.A. |
| (DMS) | | | |
| Paraffin C16~C18 | 20-22 | 152 | N.A. |
| Pologlycol E600 | 22 | 127.2 | 0.189 |
| | | | 0.187 |
| Paraffin C13~C24 | 22-24 | 189 | 0.21 |
| 1-dodecanol | 26 | 200 | N.A. |
| | | 188.8 | |
| Paraffin C18 | 28 | 244 | 0.148 |
| | 27.5 | 243.5 | 0.15 |
| | 22.5-26.2 | 205.1 | 0.358 |
| Paraffin C20~C33 | 48-50 | 189 | 0.21 |
| Paraffin C22~C45 | 58-60 | 189 | 0.21 |
| Paraffin Wax | 64 | 173.6 | 0.167 |
| | | 266 | 0.346 |
| | | | 0.339 |
| Pologlycol E6000 | 66 | 190.0 | N.A. |
| Paraffin C21~C50 | 66-68 | 189 | 0.21 |

In the disclosure and the following embodiments, the paraffin wax has a melting point of approximately 64° C. When heat is applied during the fabrication of the heat transfer portion 300, a portion of the paraffin wax may melt and acquire a rubber-like consistency. As a result, when the coating layer 330 is applied to the paraffin wax, the coating layer 330 may come into close contact with the base layers 310 and 320, thereby strengthening the bond between the coating layer 330 and the base layers 310 and 320.

The following table presents materials capable of undergoing phase change at specific temperatures, which may be used for the base layers 310 and 320.

TABLE 2

| | Type of | Melting | Latent Heat |
|---|---|---|---|
| PCM Name | Material | Point | of Fusion |
| RT20 | Paraffin | 22 | 172 |
| ClimSel C 24 | N.A. | 24 | 108 |
| RT26 | Paraffin | 25 | 131 |
| STL27 | Salt hydrate | 27 | 213 |
| AC27 | Salt hydrate | 27 | 207 |
| RT27 | Paraffin | 28 | 179 |
| TH29 | Salt hydrate | 29 | 188 |
| STL47 | Salt hydrate | 47 | 221 |
| ClimSel C 48 | N.A. | 48 | 227 |
| STL52 | Salt hydrate | 52 | 201 |
| RT54 | Paraffin | 55 | 179 |
| STL52 | Salt hydrate | 55 | 242 |
| TH58 | N.A. | 58 | 226 |
| ClimSel C 58 | N.A. | 58 | 259 |
| RT65 | Paraffin | 64 | 173 |
| ClimSel C 70 | N.A. | 70 | 194 |

According to an embodiment, the base layers 310 and 320 forming the encapsulation structure may comprise the phase-changeable materials (e.g., PCM, Phase Change Material) listed in the table.

According to an embodiment, the base layers 310 and 320 may undergo a phase change from a solid state to a rubber-like state at a specific temperature. As a result, the heat transfer portion 300 may eliminate any air layer that may be formed between the heat transfer portion 300 and a heat source (e.g., an application processor (AP) or a power management integrated circuit (PMIC)) and may more tightly adhere to and bond with the heat source.

Accordingly, interfacial thermal resistance, which is the thermal resistance occurring at the interface where two different materials come into contact, may be reduced. Due to the reduction in interfacial thermal resistance, the heat transfer portion 300 may exhibit improved heat dissipation effect.

According to an embodiment, the phase-changeable material may lack a restoring force to return to a solid state. As a result, after the base layers 310 and 320 undergo a phase change into a rubber-like state at a specific temperature, they may not return to a solid state, thereby preventing/reducing surface defects that may occur during the solidification process.

Referring to FIG. 8B, the materials that may be used for the base layers 310 and 320, as described above, may have an atomic structure including a plurality of hydrogen functional groups (—H). The components of the base layers 310 and 320 are not limited to the components and materials described above and may include other components and materials capable of chemically bonding with the coating layer 330.

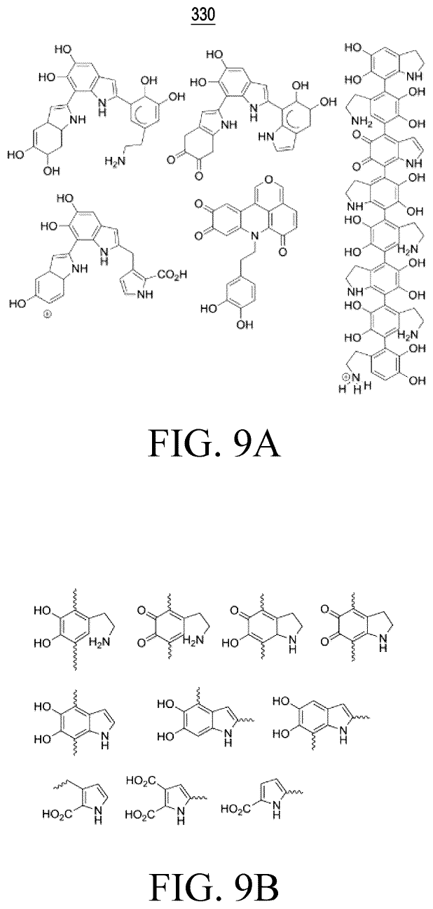

FIG. 9A is a diagram illustrating an example chemical structure of a coating layer 330 according to various embodiments. FIG. 9B is a diagram illustrating the chemical structure of an example monomer unit of the coating layer 330 in FIG. 9A according to various embodiments.

Referring to FIGS. 9A and 9B, the coating layer 330 may be a polymer comprising various monomer units. According to an embodiment, the coating layer 330 may be polydopamine. According to an embodiment, polydopamine, as a material forming the coating layer 330, may readily bond with paraffin wax forming the base layers 310 and 320.

Polydopamine is a polymer formed by the self-polymerization of dopamine and may include a plurality of monomer units capable of coordinating with metal ions. According to an embodiment, polydopamine may include various monomer units that include multiple functional groups, such as hydroxyl groups (-OH) and amino groups (—NH).

Due to these various monomer units, polydopamine may readily bind with phase-changeable materials (e.g., PCM (Phase Change Material)), which are materials of the base layers 310 and 320 described above. Accordingly, when the bonding between the base layers 310 and 320 is weak, polydopamine, which includes multiple functional groups, may enhance the bonding force between the base layers 310 and 320. As the bonding force between the base layers 310 and 320 increases, the thickness of the heat transfer portion 300 may be further reduced.

In various example embodiments of the disclosure, the base layers 310 and 320 are described as using phase-changeable materials, and the coating layer 330 is provided as an example of using polydopamine. However, this disclosure is not limited thereto, and if the bonding between the base layers 310 and 320 and the bonding between the coating layer 330 and the heat dissipating material 340 are strengthened via the coating layer 330, other polymers may also be used.

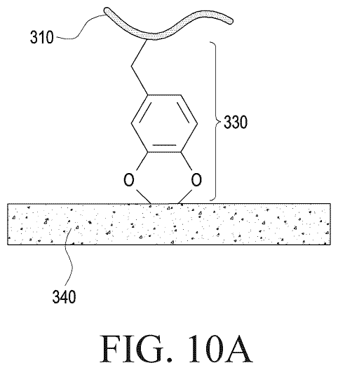

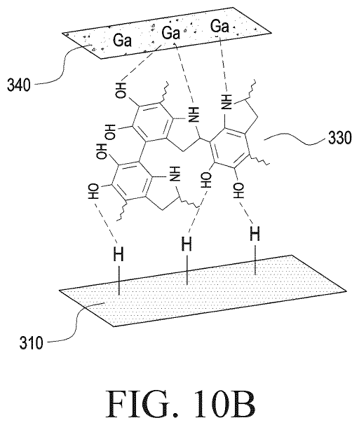

FIG. 10A is a diagram illustrating example bonding between the coating layer 330 and the first base layer 310, and the bonding between the coating layer 330 and the heat dissipating material 340, according to various embodiments. FIG. 10B is a diagram illustrating example bonding between the coating layer 330 and the first base layer 310, and the bonding between the coating layer 330 and the heat dissipating material 340, according to various embodiments.

Referring to FIGS. 10A and 10B, the coating layer 330 is disposed between the first base layer 310 and the heat dissipating material 340 and may bond to the first base layer 310 and/or the heat dissipating material 340. According to an embodiment, when the heat dissipating material 340 is applied onto the base layers 310 and 320 on which the coating layer 330 is disposed, secondary chemical bonding (e.g., a coordinative bond) may occur between major metal atoms (e.g., Ga, Bi, In) forming the heat dissipating material 340 and functional groups of the coating layer 330 (e.g., amino groups (—NH) and hydroxyl groups (—OH)). As a result, a chemical bond may be formed between the coating layer 330 and the heat dissipating material 340, enabling the coating layer 330 to control the fluidity of the heat dissipating material 340.

According to an embodiment, hydrogen atoms are disposed at the outer edges of the base layers 310 and 320, and highly electronegative atoms such as oxygen, nitrogen, and fluorine, among the atoms of the monomer units forming the coating layer 330, are also disposed at the outer edges. Consequently, hydrogen bonding may be formed between the hydrogen atoms disposed at the outer edges of the base layers and the coating layer 330.

After hydrogen bonding is formed between the base layers 310 and 320 and the coating layer 330, the heat dissipating material 340 may be disposed on the coating layer 330, and covalent bonding may be formed between the coating layer 330 and the heat dissipating material 340.

In the various example embodiments of the disclosure, an example is provided in which the functional group of the coating layer 330 is an amino group (—NH) and forms a coordinative bond with the metal atoms of the heat dissipating material 340. However, this disclosure is not limited thereto, and if a chemical bond is formed between the coating layer 330 and the heat dissipating material 340, and accordingly, the fluidity of the heat dissipating material 340 is controlled, the bond between the coating layer 330 and the heat dissipating material 340 may be a covalent bond.

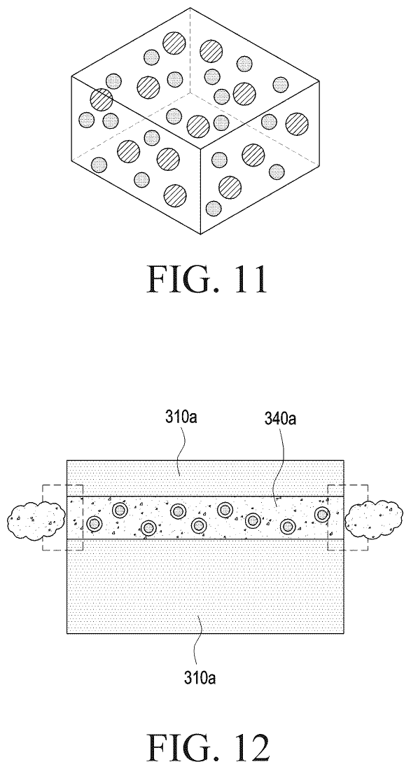

FIG. 11 is a diagram illustrating a comparative example according to various embodiments. FIG. 12 is a diagram illustrating a comparative example according to various embodiments.

Referring to FIG. 11, as a comparative example, there may be a case in which solid metal particles and/or liquid metal particles are filled into a polymer resin. According to the comparative example of FIG. 11, when a solid heat dissipating material is used, the low fluidity of the heat dissipating material may prevent and/or reduce contamination and/or malfunction caused by leakage of the heat dissipating material. However, a heat transfer portion in which metal particles are filled into a solid heat dissipating material may have lower thermal conductivity than the heat transfer portion 300 of the disclosure.

Additionally, when manufacturing the heat transfer portion 300 using the liquid heat dissipating material 340, the fluidity of the liquid heat dissipating material 340 may not be controlled, making it prone to leakage under external pressure. Even when a solid-phase binder is used along with the liquid heat dissipating material 340, controlling the fluidity may still be challenging.

Referring to FIG. 11, after the heat dissipating material 340a is disposed on the base layer 310a, another base layer 310a may be disposed thereon to protect the heat dissipating material 340a. According to the comparative example, if the base layer 310a does not form an encapsulating structure surrounding the heat dissipating material 340a, it may prevent and/or reduce leakage of the heat dissipating material 340a in the vertical direction. However, the heat dissipating material 340a may still be exposed at the lateral sides. As a result, the heat dissipating material 340a may leak in the direction of the exposed lateral sides, potentially causing malfunction and/or contamination of the electronic device 101.

In the comparative example, the base layer 310a used to protect the heat dissipating material 340a may have lower thermal conductivity (e.g., 0.5 W/mK) than the liquid heat dissipating material 340a. Consequently, when the heat transfer portion 300a transfers heat in the vertical direction, high thermal resistance may occur, thereby reducing heat transfer efficiency.

According to an embodiment of the disclosure, while an encapsulating structure capable of controlling the lateral leakage of the heat dissipating material 340 is applied, a chemical bond may also be formed between the heat dissipating material 340 and the coating layer 330 to control fluidity. Furthermore, using a highly thermally conductive liquid heat dissipating material 340, a heat transfer portion 300 with high heat transfer efficiency may be provided.

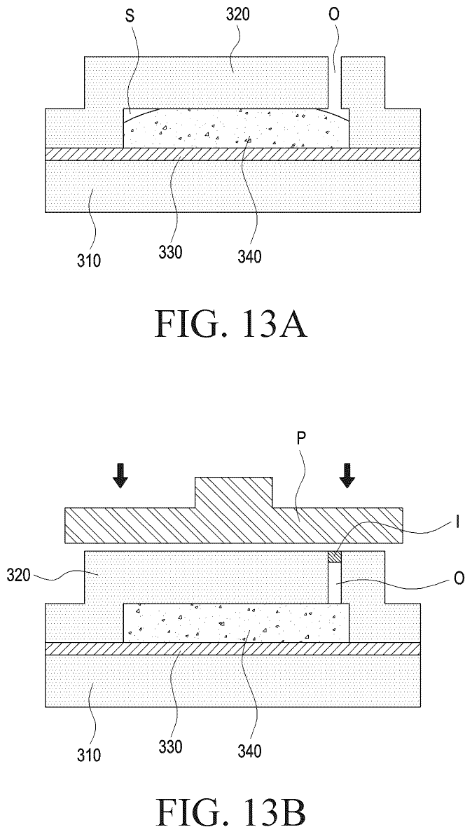

FIG. 13A is a cross-sectional view of the heat transfer portion 300 when an opening O is formed, according to various embodiments. FIG. 13B is a cross-sectional view of the heat transfer portion 300 when an opening O is formed, according to various embodiments.

Referring to FIGS. 13A and 13B, when an encapsulating structure is implemented in the heat transfer portion 300, an internal space S (e.g., a space between the second base layer 320 and the heat dissipating material 340) may be formed. When the internal space S, which contains air with low thermal transfer efficiency, is formed inside the heat transfer portion 300, the heat transfer efficiency to the exterior of the heat transfer portion 300 may be reduced.

According to an embodiment, in order to eliminate the internal space S of the encapsulating structure and improve the heat transfer efficiency of the heat transfer portion 300, an opening O may be additionally formed at one end of the base layers 310 and 320. When the internal space S is removed by forming the opening O at one end of the base layers 310 and 320, the heat dissipating material 340 may flow out along with air due to the fluidity of the heat dissipating material 340.

According to an embodiment, in order to prevent and/or inhibit the heat dissipating material 340 from flowing out through the opening O, the heat transfer portion 300 may further include an insertion portion I. The insertion portion I may be inserted into and fixed at the opening O through a pressure portion P. For example, the pressure portion P may apply heat and pressure to the insertion portion I, and through the applied heat and pressure, the insertion portion I may be fixed between the base layers 310 and 320, thereby preventing/reducing leakage of the heat dissipating material 340.

According to an embodiment, the insertion portion I may be made of the same material (e.g., paraffin wax) as the base layers 310 and 320. Since the material forming the base layers 310 and 320 is a phase-changeable material under specific conditions, the insertion portion I may undergo a phase change at a temperature equal to or higher than the glass transition temperature.

Accordingly, under the heat and pressure applied by the pressure portion P, the insertion portion I may transform into a rubber-like form, and the transformed rubber-like insertion portion I may closely adhere to and bond with the base layers 310 and 320. As a result, the insertion portion I may bond with the base layers 310 and 320 with a high bonding force.

According to an embodiment, due to the formation of the opening O and the bonding of the insertion portion I, the internal space S of the heat transfer portion 300 may be effectively eliminated without leakage of the heat dissipating material 340.

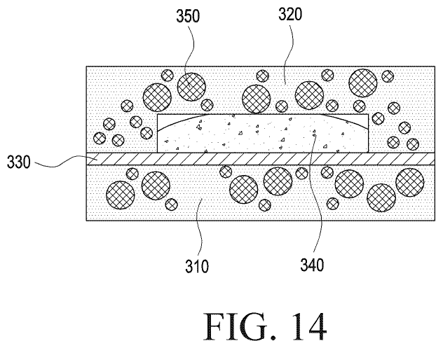

FIG. 14 is a cross-sectional view of the heat transfer portion 300 when filler particles 350 are filled in the base layers 310 and 320, according to various embodiments.

Referring to FIG. 14, the base layers 310 and 320, which are used to control the fluidity of the heat dissipating material 340, may generally be made of materials with low thermal conductivity. Since the base layers 310 and 320 with low thermal conductivity are present on the path through which heat is transferred to the exterior for heat dissipation, the use of the base layers 310 and 320 with low thermal conductivity may reduce the heat transfer efficiency of the heat transfer portion 300.

According to an embodiment, the heat transfer portion 300 may further include filler particles 350 with high heat dissipation efficiency in the base layers 310 and 320. As a result, the base layers 310 and 320 may have higher thermal conductivity compared to when the filler particles 350 are not included.

The filler particles 350 may include particles such as carbon-based particles and ceramic particles, which are commonly used for heat dissipation. Since these particles can store thermal energy and undergo a phase change, they may effectively enhance the heat transfer efficiency of the base layers 310 and 320.

According to an embodiment, when the base layers 310 and 320 further include filler particles 350 with high heat transfer efficiency, the base layers 310 and 320 may have high thermal conductivity (e.g., 3 W/mK or more). Accordingly, the base layers 310 and 320 including the filler particles 350 may more effectively transfer heat generated by the board assembly 240a to the exterior compared to the base layers 310 and 320 that do not include the filler particles 350.

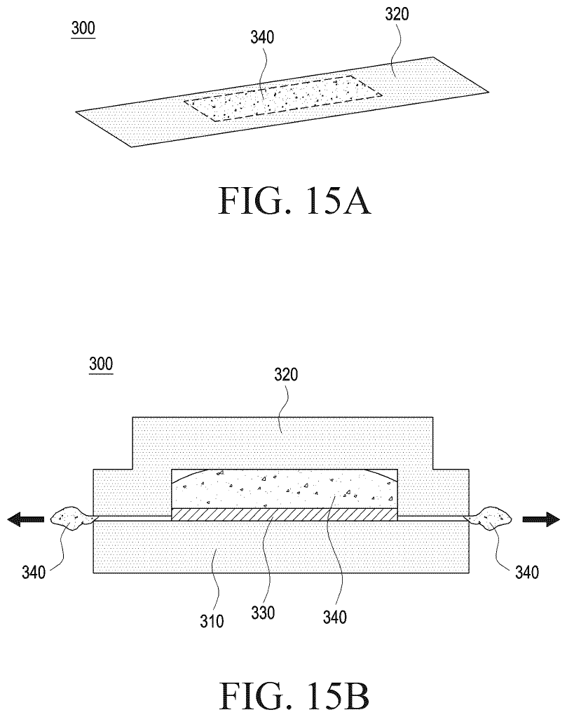

FIG. 15A is a perspective view of the heat transfer portion 300 with an encapsulating structure, according to various embodiments. FIG. 15B is a cross-sectional view of the heat transfer portion 300 according to a comparative example that contrasts with the encapsulating structure, according to various embodiments.

Referring to FIG. 15A, when the heat dissipating material 340 is applied to the surface of the base layers 310 and 320, the heat dissipating material 340 may leak to the exterior of the heat transfer portion 300 due to the low bonding energy of the surfaces of the base layers 310 and 320 and the high fluidity of the liquid heat dissipating material 340. Accordingly, as shown in FIG. 15A, the heat transfer portion 300 may have an encapsulating structure.

Referring to the comparative example in FIG. 15B, the coating layer 330 may not be disposed between the base layers 310 and 320. When the coating layer 330 is absent between the base layers 310 and 320, the bonding force between the base layers 310 and 320 may be weaker than when the coating layer 330 is present, which may result in an incompletely formed encapsulating structure. Consequently, the heat dissipating material 340 may leak between the first base layer 310 and the second base layer 320.

To prevent and/or reduce the leakage of the heat dissipating material 340, the coating layer 330 may be utilized to increase the bonding force between the first base layer 310 and the second base layer 320. The increased bonding force may then be used to form the encapsulating structure of the heat transfer portion 300.

According to an embodiment, when a strong bonding force is formed between the first base layer 310 and the second base layer 320 using the coating layer 330, and such a strong bonding force between the base layers 310 and 320 is utilized to form the encapsulating structure, the fluidity of the heat dissipating material 340 may be more effectively controlled.

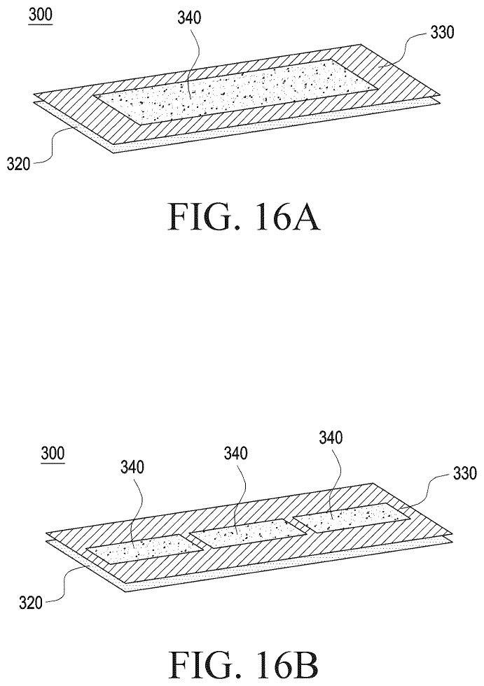

FIG. 16A is a diagram illustrating the heat transfer portion 300 according to various embodiments. FIG. 16B is a diagram illustrating the heat transfer portion 300 in which a plurality of heat dissipating materials 340 are spaced apart from each other, according to various embodiments.

Referring to FIGS. 16A and 16B, the heat transfer portion 300 may be formed with a plurality of heat dissipating materials 340 that are spaced apart in various shapes. In the disclosure, an example is provided in which the heat dissipating materials 340 are formed in a rectangular shape; however, the disclosure is not limited thereto, and the heat dissipating materials 340 may be formed in various shapes and quantities depending on the heat dissipation effect that the heat transfer portion 300 aims to achieve.

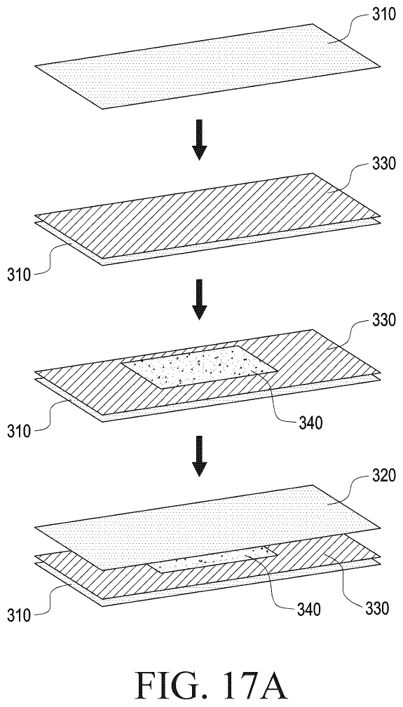

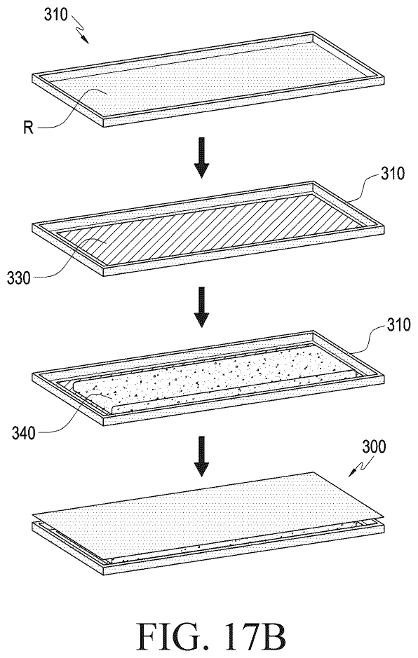

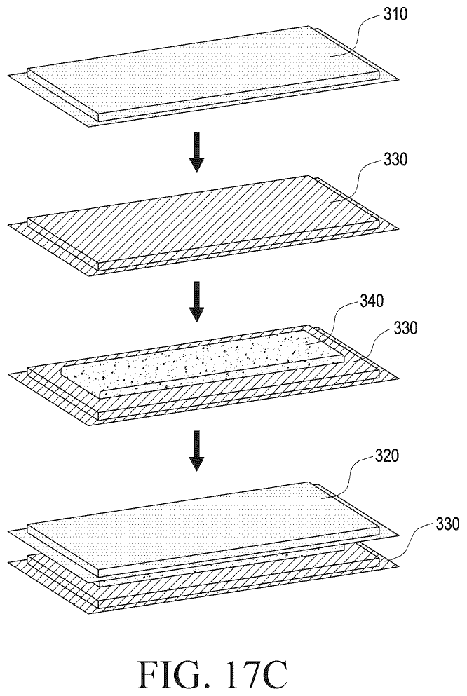

FIG. 17A is a diagram illustrating an example process of forming the heat transfer portion 300 when the first base layer 310 is flat, according to various embodiments. FIG. 17B is a diagram illustrating an example process of forming the heat transfer portion 300 when the first base layer 310 is concave, according to various embodiments. FIG. 17C is a diagram illustrating an example process of forming the heat transfer portion 300 when the first base layer 310 is convex, according to various embodiments.

Referring to FIGS. 17A, 17B, and 17C, the first base layer 310 may have a flat shape, a concave shape including a recess R, or at least a partially convex shape. Depending on the shape of the first base layer 310, the method of forming the encapsulating structure of the base layers 310 and 320 may vary, and the position where the heat transfer portion 300 is applied may also differ.

Referring to FIG. 17A, when the first base layer 310 has a flat shape, the coating layer 330 may be disposed on the first base layer 310, the heat dissipating material 340 may be disposed on at least a portion of the coating layer 330, and the second base layer 320 may be disposed on the heat dissipating material 340. When the first base layer 310 is formed as a flat shape, the heat transfer portion 300 may be formed thinner than in the example embodiments of FIGS. 17B or 17C. As a result, the heat transfer portion 300 may be positioned at various locations within the electronic device 101.

Referring to FIG. 17B, the first base layer 310 may have a concave shape including a recess R. The coating layer 330 may be disposed on the recess R, and the heat dissipating material 340 may be disposed on the coating layer 330. Additionally, the second base layer 320 may surround the heat dissipating material 340 and may be disposed over the recess R and/or the entire first base layer 310.

According to an embodiment, the coating layer 330 may be disposed on the recess R, while the coating layer 330 may not be disposed on other portions of the first base layer 310 except for the recess R. As a result, when bonding the base layers 310 and 320, the coating layer 330 may not be used, and the bonding force between the base layers 310 and 320 may be weak or may not form at all.

Referring to FIG. 17B, since the heat dissipating material 340 is disposed inside the recess R, even if the bonding force between the base layers 310 and 320 is weak or bonding does not occur, the fluidity of the heat dissipating material 340 may still be effectively controlled.

In addition, when the first base layer 310 including the recess R is provided, the heat transfer portion 300 may include a greater amount of the heat dissipating material 340, thereby providing a heat transfer portion 300 with improved heat dissipation performance.

Referring to FIG. 17C, when the first base layer 310 has a convex shape, the coating layer 330 may be disposed on the first base layer 310, the heat dissipating material 340 may be disposed on the convex shape, and the second base layer 320 may be disposed to surround the heat dissipating material 340.

The example embodiments of FIGS. 17A, 17B, and 17C may be selectively applied depending on the required heat dissipation efficiency, thickness, and other conditions of the heat transfer portion 300.

The disclosure relates to an electronic device. The electronic device 101 may include a housing 210 and a board assembly 240a disposed inside the housing 210. The board assembly 240a may include a printed circuit board 243 having a first surface 243a and a second surface 243b, an electronic component 241 disposed on the first surface 240a of the board assembly, a shielding portion disposed on the first surface 243a and surrounding the electronic component 241, the shielding portion including a first support portion 244a forming a receiving space 242 and a shielding sheet 246 covering the receiving space 242, and a heat transfer portion 300 disposed between the electronic component and the shielding sheet and configured to exchange heat with the electronic component, wherein the heat transfer portion 300 may include a first base layer 310 disposed on the electronic component, a coating layer 330 disposed on the first base layer 310, a heat dissipating material 340 disposed on the coating layer 330 and chemically bonded to the coating layer 330, and a second base layer 320 disposed on the heat dissipating material 340.

According to an embodiment, the electronic device may be configured such that the heat dissipating material 340 is liquid at room temperature.

According to an embodiment, the electronic device may be configured such that the first base layer 310 and/or the second base layer 320 are solid at room temperature.

According to an embodiment, the electronic device may be configured such that the chemical bond between the coating layer 330 and the heat dissipating material 340 is a coordinative bond.

According to an embodiment, the electronic device may be configured such that the coating layer 330 is chemically bonded to at least one of the first base layer 310 or the second base layer 320.

According to an embodiment, the electronic device may be configured such that the chemical bond between the coating layer 330 and at least one of the first base layer 310 or the second base layer 320 is a hydrogen bond.

According to an embodiment, the electronic device may be configured such that the coating layer 330 includes poly-dopamine.

According to an embodiment, the electronic device may be configured such that the heat dissipating material 340 includes at least one of metals such as gallium (Ga), bismuth (Bi), indium (In), and tin (Sn).

According to an embodiment, the electronic device may be configured such that the heat dissipating material 340 includes a metal, wherein the metal includes at least one of gallium (Ga), bismuth (Bi), indium (In), and tin (Sn).

According to an embodiment, the electronic device may be configured such that the first base layer 310 and/or the second base layer 320 further includes an opening O.

According to an embodiment, the electronic device may be configured such that the first base layer 310 and/or the second base layer 320 further includes an insertion portion I inserted into the opening O.

According to an embodiment, the electronic device may be configured such that the first base layer 310 and/or the second base layer 320 further includes at least one of ceramic, composite ceramic, carbon, or metal.

According to an embodiment, the electronic device may be configured such that the heat dissipating material 340 is spaced apart and disposed in a plurality of areas on the coating layer 330.

According to an embodiment, the electronic device may be configured such that the first base layer 310 includes a recess R formed in a portion thereof.

According to an embodiment, the electronic device may be configured such that the coating layer 330 is disposed on the recess R, and the heat dissipating material 340 is disposed on the coating layer 330.

The disclosure relates to a heat transfer portion. According to an embodiment, the heat transfer portion 300 may include a first base layer 310, a coating layer 330 disposed on the first base layer 310, a heat dissipating material 340 disposed on the coating layer 330 and chemically bonded to the coating layer 330, and a second base layer 320 disposed on the heat dissipating material 340.

According to an embodiment, the heat transfer portion may be configured such that the heat dissipating material 340 is liquid at room temperature.

According to an embodiment, the heat transfer portion may be configured such that the coating layer 330 is chemically bonded to at least one of the first base layer 310 or the second base layer 320.

The disclosure relates to a manufacturing method. According to an embodiment of the disclosure, a method of manufacturing a heat transfer portion may include: manufacturing a first base layer; coating a coating layer on the first base layer; applying a liquid heat dissipating material on the coating layer; and laminating a second base layer onto the heat dissipating material and the coating layer, wherein the coating layer and the heat dissipating material are chemically bonded.

According to an embodiment, the manufacturing method may be configured such that the coating layer is chemically bonded to at least one of the first base layer or the second base layer.

According to an embodiment, by providing a heat transfer portion including a liquid heat dissipating material, an electronic device with improved heat dissipation performance may be provided, compared to an electronic device including a heat transfer portion that does not include a liquid heat dissipating material.

According to an embodiment, when a heat transfer portion having an encapsulating structure that includes a liquid heat dissipating material is disposed on a main heat source (e.g., the top of an application processor (AP) chip), the temperature of the main heat source may be at least 2.1° C. lower than when a heat transfer portion that does not include a liquid heat dissipating material is used.

According to an embodiment, an encapsulating structure may be formed in the heat transfer portion including a liquid heat dissipating material, and the chemical bond between the coating layer and the heat dissipating material may be used to control the fluidity of the liquid heat dissipating material. As a result, leakage of the liquid heat dissipating material may be prevented/reduced, and an electronic device may be provided in which malfunction and/or contamination caused by the leakage of the heat dissipating material may be prevented/reduced.

The electronic device 101 described through the various example embodiments of the present disclosure is not limited to the foregoing example embodiments and the accompanying drawings, and it will be apparent to those skilled in the art that various substitutions, modifications, and changes may be made within the technical scope of the present disclosure. It will also be understood that any of the embodiment(s) described herein may be used in connection with any other embodiment(s) described herein.

What is claimed is:

1. An electronic device comprising:
a housing;
a board assembly disposed in the housing, comprising:
a printed circuit board including a first surface and a second surface;
an electronic component disposed on the first surface of the board assembly;
a shielding portion disposed on the first surface and at least partially surrounding the electronic component, and including a first support portion defining a receiving space, and a shielding sheet at least partially covering the receiving space; and
a heat transfer portion disposed between the electronic component and the shielding sheet and configured to exchange heat with the electronic component,
wherein the heat transfer portion includes:
a first base layer disposed on the electronic component;
a coating layer disposed on the first base layer,
a heat dissipating material disposed on the coating layer and chemically bonded to the coating layer; and
a second base layer disposed on the heat dissipation material.

2. The electronic device of claim 1, wherein the heat dissipating material is liquid at room temperature.

3. The electronic device of claim 1, wherein the first base layer and/or the second base layer are solid at room temperature.

4. The electronic device of claim 1, wherein the chemical bond between the coating layer and the heat dissipation material is a coordinative bond.

5. The electronic device of claim 1, wherein the coating layer is chemically bonded to at least one of the first base layer or the second base layer.

6. The electronic device of claim 1, wherein the chemical bond between the coating layer and at least one of the first base layer or the second base layer is a hydrogen bond.

7. The electronic device of claim 1, wherein the coating layer includes poly-dopamine.

8. The electronic device of claim 1, wherein the first base layer and/or the second base layer include paraffin wax.

9. The electronic device of claim 1,
wherein the heat dissipation material includes a metal, and
wherein the metal includes at least one of gallium (Ga), bismuth (Bi), indium (In), or tin (Sn).

10. The electronic device of claim 1, wherein the first base layer and/or the second base layer include an opening.

11. The electronic device of claim 1, wherein the first base layer and/or the second base layer further include an insertion portion inserted into the opening.

12. The electronic device of claim 1, wherein the first base layer and/or the second base layer further include at least one of ceramic, composite ceramic, carbon, or metal.

13. The electronic device of claim 1, wherein the heat dissipating material is disposed on a plurality of areas spaced apart on the coating layer.

14. The electronic device of claim 1, wherein the first base layer includes a recess formed in a portion thereof.

15. The electronic device of claim 14,
wherein the coating layer is disposed on the recess,
wherein the heat dissipating material is disposed on the coating layer.

16. A heat transfer portion comprising:
a first base layer;
a coating layer disposed on the first base layer;
a heat dissipation material disposed on the coating layer and coordinatively bonded to the coating layer; and
a second base layer disposed on the heat dissipation material.

17. The heat transfer portion of claim 16, wherein the heat dissipation material is liquid at room temperature.

18. The heat transfer portion of claim 16, wherein the coating layer is chemically bonded to at least one of the first base layer or the second base layer.

19. A method of manufacturing a heat transfer portion, the method comprising:
manufacturing a first base layer;
coating a coating layer on the first base layer;
applying a liquid heat dissipation material to the coating layer; and
laminating a second base layer to the heat dissipation material and the coating layer,
wherein the coating layer and the heat dissipation material are coordinatively bonded.

20. The method of claim 19, wherein the coating layer is chemically bonded to at least one of the first base layer or the second base layer.
